(19) United States
(12) Patent Application Publication
(10) Pub. No.: US 2015/0090320 A1
(43) Pub. Date: Apr. 2, 2015

(54) SOLAR CELL

(71) Applicant: UNIVERSIDAD POLITECNICA DE MADRID, Madrid (ES)

(72) Inventors: Antonio MARTÍ VEGA, Madrid (ES); Antonio LUQUE LÓPEZ, Madrid (ES)

(21) Appl. No.: 14/040,999

(22) Filed: Sep. 30, 2013

(51) Int. Cl. H01L 31/0687

(52) U.S. Cl. CPC H01L 31/0687
USPC 136/255

(57) ABSTRACT

A solar cell comprises a three layer semiconductor structure wherein the top (14) and middle (15) layer are made of a semiconductor of higher bandgap than the bottom layer (16), the middle layer (15) has a higher dopant concentration than the top layer (14), and the three layer semiconductor structure is either a p-n-p structure or an n-p-n structure. The solar cell includes three terminals or contacts: a top contact (17) contacting the top layer (14), a middle contact (18) contacting the middle layer (15) and a bottom contact (19) contacting the bottom layer (16). Light anti-reflecting layers and semiconductor layers to reduce surface recombination can also be added to the basic three layer semiconductor structure.

### TECHNICAL FIELD OF THE INVENTION

The present invention belongs to the field of solar cells.

### BACKGROUND OF THE INVENTION

Single gap solar cells are made of a single bandgap semiconductor. The energy of the bandgap of this semiconductor, E_{G}, is the main parameter limiting the performance of these single gap solar cells, since photons from the sun having energy lower than this bandgap cannot be absorbed. To the inventors' knowledge, the first patent of a single gap solar cell was based on silicon and was issued on Feb. 5, 1957 to Chapin, Fuller, and Pearson as U.S. Pat. No. 2,780,765 entitled “Solar Energy Converting Apparatus.”

The basic structure of a single gap solar cell is that of a p-n junction, including a p-type semiconductor (1) and an n-type semiconductor (2), as illustrated in FIG. 1. In this drawing it is assumed that the sun (6) first illuminates the n-side of the cell. This single gap solar cell has also metallic contacts including a first contact (3) contacting the n-type semiconductor and including a second contact (4) contacting the p-type semiconductor, with such contacts allowing electrical photo-generated current (7) to be extracted from the cell and to be directed to a load (5). This load is represented in the figure by a resistor and is the place where the electrical energy produced by the solar is consumed or stored. The layout of the metal contacting the semiconductor first facing the sun typically exhibits a grid geometry. Since metal is opaque to sunlight, the holes left in this grid still allow sunlight to reach the p-n structure where it can be converted into electricity.

A limitation of single gap solar cells is that only photons with energy above the semiconductor bandgap are absorbed by these cells. To overcome this limitation of photons with energy below the bandgap being wasted, multijunction solar cells have been proposed. See, e.g., E. D. Jackson, “Areas for improvement of the solar energy converter,” Trans. Conf. on the Use of Solar Energy, Tucson, 1955, University of Arizona Press, Tucson 5, 122-126 (1958). Under this approach, cells with different gaps are piled one over the other, the one with the highest bandgap being the first facing the sun and the others being located behind this one in decreasing order of their bandgaps. FIG. 2 illustrates a multijunction solar cell formed by two solar cells. Under this approach, the so-called top-cell, in its more fundamental configuration, would be formed by a p-n junction made of a high bandgap semiconductor and the so-called bottom cell would consist of a p-n junction made of a semiconductor of lower bandgap. In FIG. 2, (7) and (8) indicate respectively the n-type and p-type semiconductors of the top cell and (9) and (10) indicate the n-type and p-type semiconductors of the bottom cell. The semiconductor of the top cell is characterized by an energy bandgap E_{H} and the semiconductor of the bottom cell is characterized by an energy bandgap E_{L}. Ideally, the top cell absorbs photons with energy higher than E_{H} allowing photons with energy lower than E_{H} to pass through towards the bottom cell. There, at the bottom cell, photons with energy higher than E_{L} are absorbed. The problem presented by this approach is how to contact the two solar cells to each other.

In this respect, the simplest solution provided for contacting the two cells relies on the use of a semiconductor tunnel junction. A tunnel junction is a p-n junction characterized by an extremely high doping of the p and n layers. The notation usually used to designate a tunnel junction is p⁺⁺-n⁺⁺. While a conventional non-illuminated p-n junction prevents electrical current from circulating from the n-side towards the p-side of the junction, a tunnel junction does allow electrical current to circulate from the n⁺⁺ side to the p⁺⁺ side of the junction. Hence, as illustrated in FIG. 3, a tunnel junction provides the means for contacting the back p-type layer (9) of the top cell with the front n-type layer (10) of the bottom cell without blocking the electrical current flow (7). In a manner similarly to the single gap solar cells, a front contact (3) and a rear metallic contact (4) can be placed on the top layer (8) of the top cell and on the back layer (11) of the bottom cell. In FIG. 3, a tunnel junction formed by a p⁺⁺ layer (12) and an n⁺⁺ layer (13) is placed between the top cell and the bottom cell. As can be observed, the total cell structure consists of a minimum of 6 layers leading to a n-p-p++-n++-n-p structure. This structure is usually known as monolithically integrated multijunction solar cell. As will be explained in the next sections, the present invention is capable of reducing the minimum number of layers from 6 to 3, thus simplifying the structure of the solar cell while maintaining its potential for high efficiency.

### SUMMARY OF THE INVENTION

The present invention provides a solar cell according to the claims, as well as a method of generating electric power utilizing at least one solar cell as described herein. The dependent claims define preferred embodiments of the invention.

In certain embodiments according to the present invention, a solar cell comprises

a three layer semiconductor structure comprising a top layer, a bottom layer, and a middle layer, the middle layer being placed between and in contact with the top layer and the bottom layer, the three layer semiconductor structure being a p-n-p structure or an n-p-n structure, and

three electrical contacts, each electrical contact being connected to a different one of the top layer, the bottom layer, and the middle layer,

wherein:

each of the top layer and the middle layer comprises at least one semiconductor having a bandgap higher than the bandgap of a semiconductor of the bottom layer, and

the middle layer has a higher dopant concentration than the top layer.

Advantageously, embodiments of the present invention allow the minimum number of layers of the monolithically integrated multijunction solar cell to be reduced to three layers.

Thus, embodiments of the invention may comprise an n-p-n or a p-n-p semiconductor structure where the top layer and the middle layer are made of a semiconductor of higher bandgap than the bottom layer and where the middle layer has a higher dopant concentration than the top layer. The top layer will be understood as the layer intended to be firstly illuminated by solar light. Three terminals or contacts are provided, with each terminal or contact being connected to a different semiconductor layer.

In certain embodiments the semiconductor structure comprises, or alternatively consists of, an n-p-n structure.

In certain embodiments the semiconductor structure comprises, or alternatively consists of, a p-n-p structure.

In certain embodiments the solar cell comprises a passivating layer provided on the top layer, on the surface intended to be exposed to the solar light, i.e. the surface of the top layer opposed to the surface of the top layer in contact with the middle layer. Advantageously, the passivating layer reduces surface recombination. In certain embodiments, this passivating layer provided on the top layer comprises, or alternatively consists of, a material with a bandgap higher than the bandgap of the top layer in order to avoid photon absorption and, because of this property, the passivating layer may also be called a window layer.

Alternatively or additionally to any previous embodiment, in certain embodiments a solar cell comprises a passivating layer provided on the bottom layer, on a surface of the bottom layer opposed to the surface of the bottom layer in contact with the middle layer. Advantageously, the passivating layer reduces surface recombination.

Some common materials used as passivating and window layers (e.g., when the solar cell is based on III-V semiconductors) are AlGaAs and Al(Ga)InP.

Alternatively or additionally to any previous embodiment, in certain embodiments a solar cell comprises a contact layer provided between at least one of the semiconductor layers (i.e., to top layer, the bottom layer, and the middle layer) and the electrical contact connected to said semiconductor layer. In certain embodiments, any two or all three of the top layer, the bottom layer, and the middle layer has associated therewith a contact layer between (i) the top layer, the bottom layer, and/or the middle layer, and (ii) the electrical contact connected to said layer(s). Advantageously, the contact layer improves the contact between the semiconductor layer and the associated electrical contact. In certain embodiments, contact layers may comprise (or alternatively consist of) the same material of the semiconductor layer to be contacted. When the semiconductor layers comprise III-V semiconductors, the one or more contact layers may comprise GaAs. In preferred embodiments, contact layers are characterized by a high doping concentration (e.g., in the range of 10¹⁹ cm⁻³).

Alternatively or additionally to any previous embodiment, in certain embodiments a solar cell comprises an anti-reflecting coating deposited on the top layer, on a surface of the top layer opposed to the surface of the top layer in contact with the middle layer. If a passivating or window layer has been deposited on the top layer, the anti-reflecting coating is deposited on top of the passivating or window layer on the surface of the passivating layer or window layer opposed to the surface in contact with the top layer. Such anti-reflecting coating preferably embodies a topmost surface of the solar cell. Advantageously, the anti-reflecting layer minimizes the amount of sunlight that is reflected by the cell. In certain embodiments, this anti-reflecting coating may comprise, or alternatively consist of, more than one layer, such as for example MgF₂/ZnS or MgF₂/Ta₂O₅ double anti-reflecting coatings.

Alternatively or additionally to any previous embodiment, in certain embodiments of the solar cell, the electrical contact connected to the top layer comprises or alternatively consists of a grid allowing light to pass through the electrical contact and thereby impinge on the top layer.

Alternatively or additionally to any previous embodiment, in certain embodiments of the solar cell the electrical contact connected to the top layer comprises or alternatively consists of a semitransparent conductor allowing light to pass through the electrical contact and thereby impinge on the top layer. An example of a semitransparent conductor useful for forming a contact for connection to a top layer is Indium tin oxide (ITO).

Alternatively or additionally to any previous embodiment, in certain embodiments of the solar cell the electrical contact connected to the bottom layer comprises or alternatively consists of a layer at least partially covering the bottom layer on a surface of the bottom layer opposed to the surface of the bottom layer in contact with the middle layer.

Alternatively or additionally to any previous embodiment, in an embodiment of the solar cell the top and middle layers are made of AlₓGa₁₋ₓAs and the bottom layer is made of Al_{y}Ga_{1-y}As, with y<x.

Alternatively or additionally to any previous embodiment, in an embodiment of the solar cell the top and middle layer comprise, or alternative consist of, GaAs and the bottom layer comprises, or alternatively consists of, Ge.

Alternatively or additionally to any previous embodiment, in certain embodiments of the solar cell, the top and middle layer comprise, or alternatively consist of, AlGaAsP and the bottom layer comprises, or alternatively consists of, Ge or GaAs or InP or Si.

The invention also provides a method of generating electric power comprising use of at least one solar cell as disclosed herein.

All the features described in this specification (including the claims, description and drawings) and/or all the steps of the described method can be combined in any combination, with the exception of combinations of such mutually exclusive features and/or steps.

### DESCRIPTION OF THE DRAWINGS

The features and advantages of the invention will become clearly understood in view of the detailed description of the invention which becomes apparent from a preferred embodiment of the invention, given just as an example and not being limited thereto, with reference to the drawings.

FIG. 1 shows a prior art single gap solar cell.

FIG. 2 shows the multijunction solar cell concept based on two solar cells.

FIG. 3 shows a structure of a monolithically integrated multijunction solar cell.

FIG. 4 shows a solar cell according to one embodiment of the invention.

FIG. 5-11 show the steps of a method to manufacture a solar cell according to one embodiment of the invention.

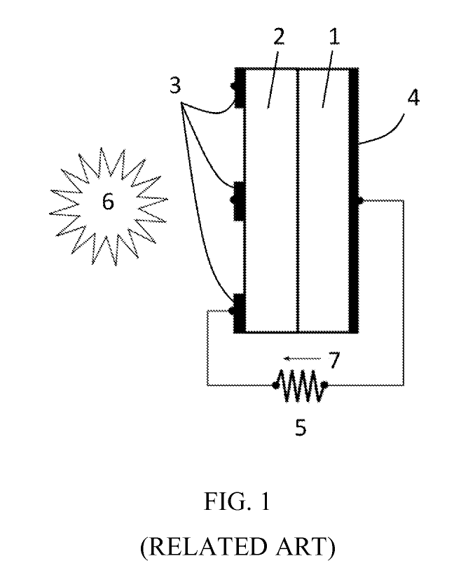

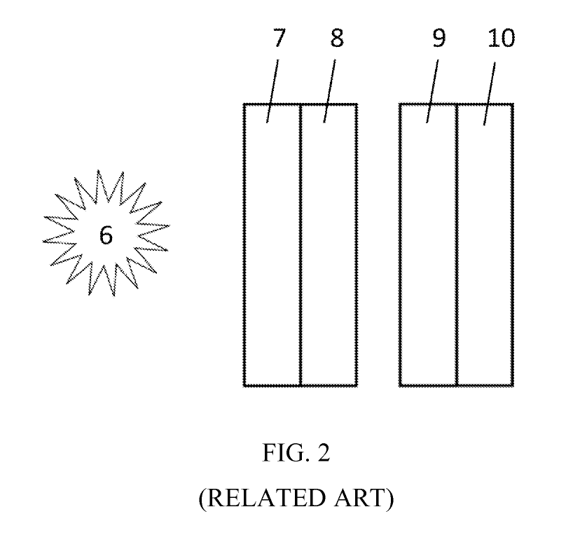

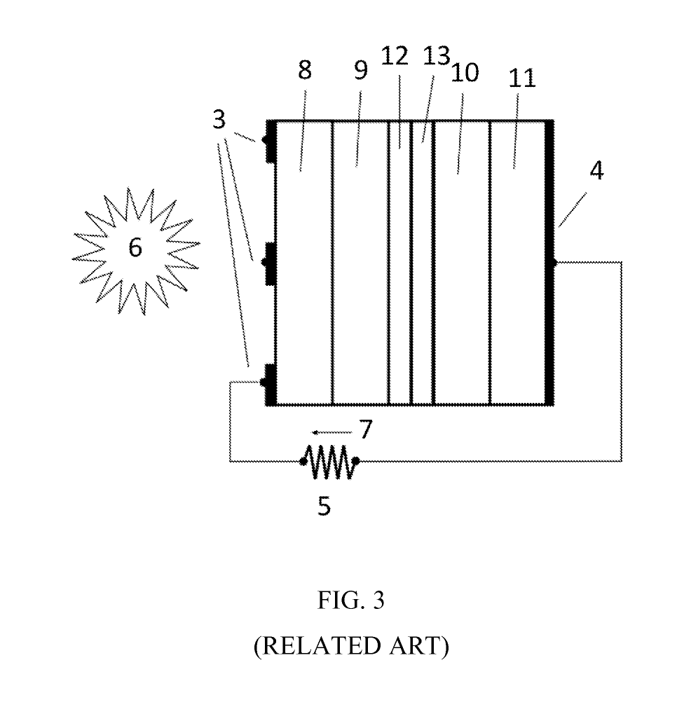

### DETAILED DESCRIPTION OF THE INVENTION

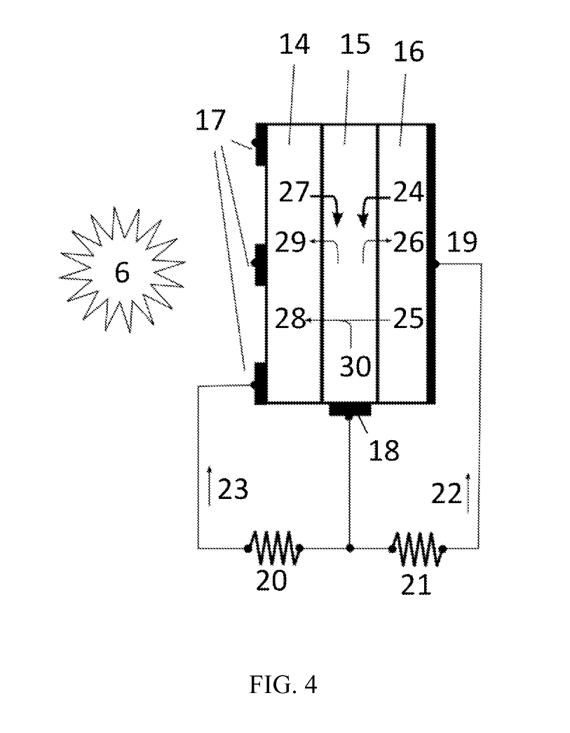

FIG. 4 shows a solar cell according to one embodiment of the invention. The fundamental structure of the solar cell includes three semiconductor layers: a top layer (14) intended to face the sun, a middle layer (15) in contact with the top layer (14) and a bottom layer (16) in contact with the middle layer (15) at the surface of the middle layer (15) opposed to the surface in contact with the top layer (14). The invention will be described on the basis of an embodiment having an n-p-n structure, i.e. the top (14) and bottom (16) layers being made of an n-type semiconductor and the middle layer (15) being made of a p-type semiconductor. However, it will be understood that the invention also works if a p-n-p structure is chosen for the three layer semiconductor structure instead of an n-p-n structure, which would just interchange the role of electrons and holes.

With continued reference to the solar cell of FIG. 4, the top layer (14) and the middle layer (15) are made of a semiconductor of higher bandgap than that of the bottom layer (16). The bandgap of the semiconductor of which the top (14) and middle (15) layers are made will be designated as E_{H} and the bandgap of the semiconductor of which the middle layer (16) is made will be designated as E_{L}. The solar cell also includes three terminals or contacts. The contact to the n top layer (14) will be denoted as “top contact” (17), the contact to the p middle layer (15) as “middle contact” (18) and the contact to the bottom layer (16) as “bottom contact” (19).

In certain embodiments, the top contact (17) does not cover completely the n-type top layer (14) but has the form of (or comprises) a metallic grid allowing light to pass through the top contact (17) and reach the semiconductor structure (e.g., the top semiconductor layer (14)). Alternatively, the top contact (17) may be made of (or comprise) a semitransparent conductor and, in this case, it can cover completely the surface of the top semiconductor layer (14).

The top (17) and middle (18) contacts are connected to a load (20). The bottom (19) and middle (18) contacts are also connected to a load (21). The electrical energy produced by the solar cell is collected at these loads. The motivation for choosing a high bandgap material for the n-type top layer and the p-type middle layer is two-fold: a) collecting the energy of those photons with energy higher than E_{H}, and b) limiting the voltage across the load (20) to E_{H}/e volts (with e being the electron charge) and not to a lower value.

The solar cell of the invention works as follows. When the cell is illuminated (e.g., with the sun or another radiation source (6)), those photons having energy lower than the bandgap E_{H} reach the bottom semiconductor layer (16) and produce electrical current. This current, I_{C} (22), flows through the load (21), where the photon energy can be collected or stored (for example, in a rechargeable battery). For later reference, the value of this load (21) will be designated as R_{BC}. The voltage across this load (21) biases the middle-bottom contacts (18, 19) with a voltage V_{BC} (higher at the p-type middle layer (15) than at the n-type bottom layer (16)). If the contact and semiconductor resistances are low, this voltage will also be approximately the voltage across the junction between the p-type middle layer (15) and the n-type bottom layer (16).

On the other hand, photons with energy higher than E_{H} are absorbed by the top (14) and middle (15) semiconductor layers. Ideally, the thickness of the n-type top layer (14) and p-type middle layer (15) should be made high enough as to absorb all photons with energy higher than E_{H}. The absorption of photons in the n-p junction formed by the top and middle semiconductor layers (14, 15) produce an electrical current I_{E} (23) that flows through the load (20), where energy can also be collected or stored. The electrical current through the load (20) biases the middle-top contacts (18, 17) with a voltage V_{BE} (higher at the p middle contact (18) than at the n top contact (17)). For later reference, the value of this load (20) will be designated as R_{BE}. If the contact and semiconductor resistances are low, this voltage will also be approximately the voltage across the junction between the p-type middle layer (15) and the n-type top layer (14).

Following a one-dimension semiconductor low injection model to explain the performance of the solar cell of the invention and neglecting the carrier recombination at the space charge region appearing at the semiconductor junctions, currents I_{C} and I_{E} can be decomposed as follows:

I_{C}=I_{LC}−I_{hC}(V_{BC})−I_{eC}(V_{BE},V_{BC}) (1a)

I_{E}=I_{LE}−I_{hE}(V_{BE})−I_{eE}(V_{BE},V_{BC}) (1b)

where:
I_{LC}, indicated by reference number 24 in FIG. 4, is the value of the current I_{C} when the cell is illuminated and R_{BE}=0 and R_{BC}=0.

I_{eC}(V_{BE},V_{BC}), indicated by reference number 25 in FIG. 4, is the electron current flowing across the p-type middle layer/n-type bottom layer junction when the cell is not illuminated, but it is assumed that the p-type middle layer/n-type bottom layer junction is biased with the voltage V_{BC} and the p-type middle layer/n-type top layer junction has been biased with a voltage V_{BE}. This current depends both on V_{BE} and V_{BC} because it is determined by the profile of minority carriers (electrons) at the n-type middle semiconductor layer.

I_{hC}(V_{BC}), indicated by reference number 26 in FIG. 4, is the hole current across the p-type middle layer/n-type bottom layer junction when the cell is not illuminated, but it is assumed that the p-type middle layer/n-type bottom layer junction is biased with the voltage V_{BC}. The direction of the arrow used in FIG. 4 to represent this current represents the positive direction of this current when this voltage is positive (which is the case when the cell operates generating electrical power). This current does not depend on V_{BE} because it is determined by the profile of minority carriers (holes) at the n-type bottom semiconductor layer.

I_{LE}, indicated by reference number 27 in FIG. 4, is the value that the current I_{E} takes when the cell is illuminated and R_{BE}=0 and R_{BC}=0.

I_{eE}(V_{BE},V_{BC}), indicated by reference number 28 in FIG. 4, is the electron current flowing across the p-type middle layer/n-type top layer junction when the cell is not illuminated, but it is assumed that the p-type middle layer/n-type bottom layer junction is biased with the voltage V_{BC} and the p-type middle layer/n-type top layer junction has been biased with a voltage V_{BE}. This current depends on both V_{BE} and V_{BC} because it is determined by the profile of minority carriers (electrons) at the n-type middle semiconductor layer.

I_{hE}(V_{BE}), indicated by reference number 29 in FIG. 4, is the hole current across the p-type middle layer/n-type bottom layer junction when the cell is not illuminated, but it is assumed that the p-type middle layer/n-type top layer junction is biased with the voltage V_{BE}. The direction of the arrow used in FIG. 4 to represent this current represents the positive direction of this current when this voltage is positive (which is the case when the cell operates generating electrical power). This current does not depend on V_{BC} because it is determined by the profile of minority carriers (holes) at the n-type top semiconductor layer.

Assuming, for simplification purposes, the same area for both the p-type middle layer/n-type top layer and p-type middle layer/n-type bottom layer semiconductor junctions, the electron currents I_{eC} (25) and I_{eE} (28) can be expressed as follows:

$$\begin{matrix}{I}_{eC} ( {V}_{BE} , {V}_{BC} ) = {I}_{0} ( exp \frac{e {V}_{BC}}{kT} - 1 ) - {α}_{T} {I}_{0} ( exp \frac{e {V}_{BE}}{kT} - 1 ) & ( 2 ) \\ {I}_{eB} ( {V}_{BE} , {V}_{BC} ) = {I}_{0} ( exp \frac{e {V}_{BE}}{kT} - 1 ) - {α}_{T} {I}_{0} ( exp \frac{e {V}_{BC}}{kT} - 1 ) & ( 3 )\end{matrix}$$

where:
I₀ is called electron reverse saturation current. This current depends on the minority carrier parameters at the p-type middle layer, such as electron lifetime, electron diffusion length, and the thickness of the p-type middle layer. It is worth emphasizing for later reference that I₀ is proportional to nᵢ²/N_{B}, with nᵢ² being the intrinsic carrier concentration of the semiconductor that constitutes the p-type middle layer and N_{B} being the doping of this middle layer (15).
α_{T} is the transport factor. It also depends on the minority carrier parameters at p-type middle layer. It is worth emphasizing that the value of α_{T} approaches one as the thickness W_{B} of p-type middle layer (15) is reduced and approaches zero as W_{B} is increased.

The current difference:

I_{rb}=I_{eE}(V_{BE},V_{BC})−I_{eC}(V_{BE},V_{BC}) (4)

represented in FIG. 4 with reference number 30, corresponds physically to the total number of electron-hole pairs (multiplied by the electron charge) recombined in the middle layer.

At this point the electrical power, P, delivered by the cell can be calculated. It is given by

P=I_{E}V_{BE}+I_{C}V_{BC}=[I_{LE}−I_{hE}(V_{BE})]V_{BE}+[I_{LC}−I_{hC}(V_{BC})]V_{BC}−Λ(V_{BE},V_{BC},α_{T}) (5)

where

$$Λ ( {V}_{BE} , {V}_{BC} , {α}_{T} ) = {I}_{0} ( exp \frac{e {V}_{BE}}{kT} - 1 ) ( {V}_{BE} - {α}_{T} {V}_{BC} ) + {I}_{0} ( exp \frac{e {V}_{BC}}{kT} - 1 ) ( {V}_{BC} - {α}_{T} {V}_{BE} ) \qquad ( 6 )$$

represents a power loss factor that has to be minimized. In this respect, the following should be observed.

The losses decrease as the factor transport, α_{T}, increases. From this point of view, for the best performance of the invention, α_{T} should approach 1, which is the maximum value this parameter can achieve. Given the dependence of this transport factor with the thickness of the p-type middle layer, the thickness of the p-type middle layer should be made as thin as possible. However, making this layer too thin could increase the ohmic losses of the device since all the current (I_{E}+I_{C}) is extracted laterally through the middle contact (18). An alternative solution, explained in the next paragraph, is thus provided.

The losses also decrease if I₀ is minimized. Since, as advanced before, this current is proportional to

$$\frac{{n}_{i}^{2}}{{N}_{B}} ,$$

I₀ can be minimized by increasing the doping N_{B} of the middle layer, which results in a top-middle junction characterized by a low injection efficiency. This efficiency is defined, without illumination, as the ratio I_{eE}(V_{BE},0)/I₀.

The solar cell of the invention has been described in terms of the minimum layers it requires to work. In order to implement the solar cell in practice, additional layers can be added to or otherwise incorporated into the solar cell. The functions of these additional layers are well-known to persons skilled in the art of designing solar cells; therefore, detailed description of these layers is not necessary. These layers include basically: layers to decrease the surface recombination of the semiconductors (known as back surface field layers), layers to produce ohmic contacts between metal and semiconductor junctions (contact layers), buffer layers to prepare semiconductor surfaces for ulterior growth, and layers to decrease light reflection (anti-reflecting layers).

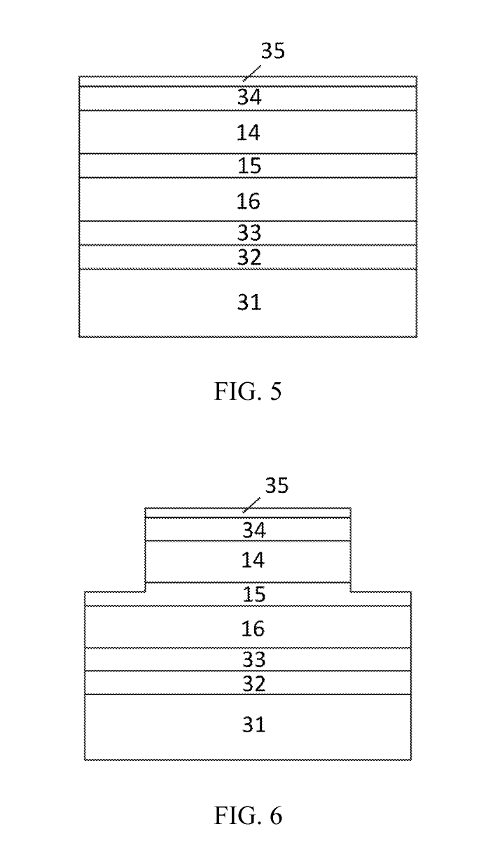

In certain embodiments, solar cells according to the invention can be fabricated by molecular beam epitaxy (MBE), as described below. FIGS. 5 to 11 help illustrate the manufacturing process of a solar cell according to certain embodiments of the invention:
A 300 μm thick n⁺-GaAs substrate, 10¹⁸ cm⁻³ silicon doped, is loaded into the MBE growth chamber. The purpose of this substrate is to provide mechanical support to the solar cell and, at a later stage, serve as a contact layer (31) for the bottom contact.
The temperature of the substrate is raised to 580 C and a 0.5 μm n⁺-GaAs layer (32) is grown at a rate of 1 μm/hr. This growth rate will remain like this for all the layers constituting the structure. This n⁺-GaAs layer (32) is a “buffer layer” and its purpose is to provide a fresh high quality GaAs layer for the subsequent material growth. It is 5·10¹⁷ cm⁻³ silicon doped.
Temperature is increased to 640 C and a 50 nm n⁺-Al_{0.3}Ga_{0.7}As layer (33) is grown. It is 2·10¹⁷ cm⁻³ silicon doped. This layer (33) acts as back surface field layer and its purpose is to decrease the surface recombination of the bottom layer.
Temperature is decreased to 580 C and an n-GaAs layer (16) is grown (5 μm, 5·10¹⁷ cm⁻³). This layer is the bottom layer (16) of the solar cell as described herein.
Temperature is increased to 640 C and a p-type Al_{0.3}Ga_{0.7}As layer (15) is grown. This layer is 0.8 μm thick and is doped with Be at a concentration of 2·10¹⁸ cm⁻³. This layer is the p-type middle layer (15) of the solar cell as described herein.
An n-type Al_{0.3}Ga_{0.7}As layer (14) is grown. This layer is the n-type top layer (14) of the solar cell as described herein. This layer is 5 μm thick and is silicon doped at a concentration of 2·10¹⁷ cm⁻³.
An n-type Al_{0.8}Ga_{0.2}As layer (34) is grown. This layer serves the purpose of decreasing the surface recombination of the n-type top layer (14). It is also a back surface field layer but since it has to be transparent to photons, it is also called window layer. It is 50 nm thick and is silicon doped at a concentration of 2·10¹⁷ cm⁻³.
Temperature is decreased to 580 C and an n⁺ GaAs layer (35) is grown. This layer is 100 nm thick and is doped with silicon at a concentration of 5·10¹⁸ cm⁻³. It is a contact layer that has the purpose of decreasing the resistance between the semiconductor and the front metallic grid that will be deposited later.

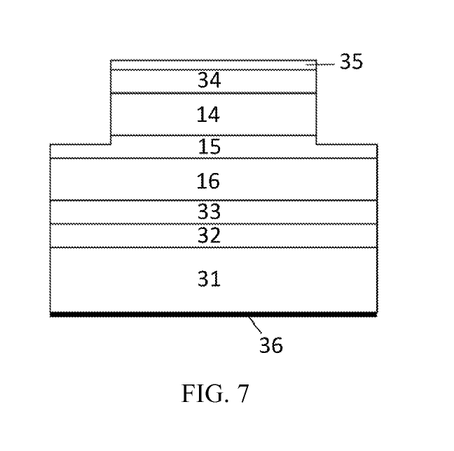

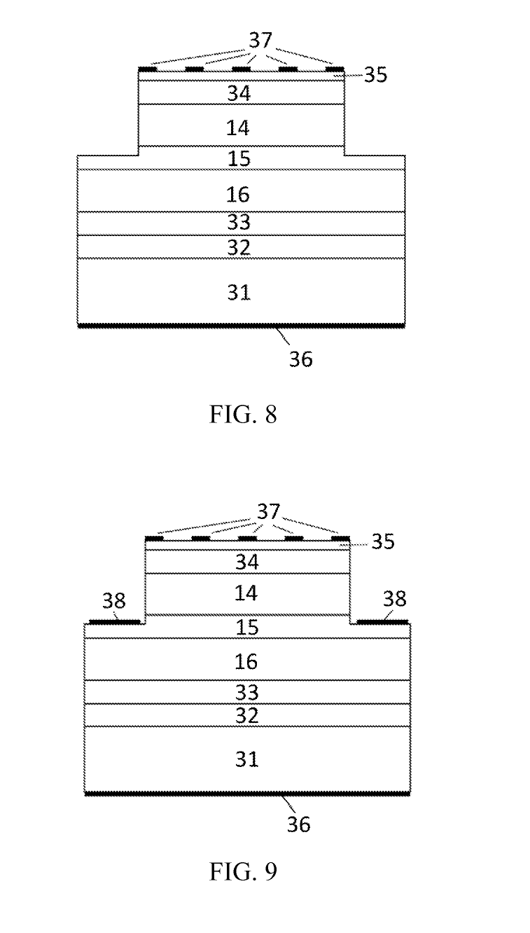

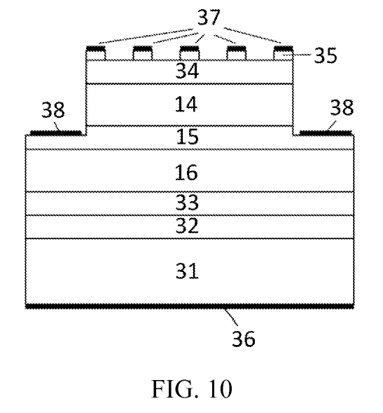

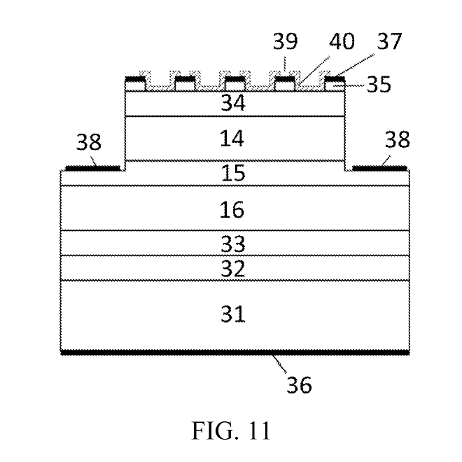

With this growth, the semiconductor structure of the cell is completed. The steps to create the contacts to the semiconductor structure are described below.
By the combined used of photolithography and controlled chemical etching, the contact layer, the window layer, and half of the thickness of the p-type middle layer (0.4 μm) are removed. The GaAs contact layer is selectively etched away using citric acid/H₂O₂ at 2.5:1 volumetric concentration ratio at room temperature. The Al_{0.8}Ga_{0.2}As window layer is selectively etched away using DI H₂O/buffered oxide etch solution (mixture of 7:1 NH₄F [36%]-HF [6.4%]) at a 10:1 volumetric concentration ratio at room temperature. The top layer and half of the middle layer are etched away using citric acid/H₂O₂ at 25:1 volumetric concentration ratio at room temperature by controlling the etching time (approximated etch rate is 20 Å/s) and providing feedback with a profiler. These layers are removed only in areas around the cell area (FIG. 6). The purpose of this etch is to create an area around the perimeter of the cell in order to reach the middle layer (15) for creating the contact to the middle layer.
An Au/Ge layer (36) is deposited at the back side of the wafer by thermal evaporation. This layer, after annealing, will create the contact to the bottom layer of the solar cell (FIG. 7).
Using photolithography, an Au/Ge layer (37) is selectively deposited over the top GaAs contact layer (35) to conform the contact to the top layer. This contact exhibits a grid pattern to allow light to pass through and enter into the top semiconductor layer of the solar cell (FIG. 8).
Using photolithography, an Au/Zn/Au layer (38) is selectively deposited over the middle layer exposed areas to conform the contact to the middle layer (FIG. 9).
Metal contacts are annealed at 350 C for 30 s.
Using selective chemical etching, the GaAs contact layer (35) is removed from the areas not covered by the front metal grid (37). The selective chemical etching consists of citric acid/H₂O₂ at 2.5:1 volumetric concentration ratio at room temperature (FIG. 10).
The cell is covered with a MgF₂/ZnS double anti-reflecting coatings (40) leaving holes (39) over the metal contacts in order to facilitate the wire bonding of the cells when integrated into a solar module (FIG. 11).

1. A solar cell comprising:
a three layer semiconductor structure comprising a top layer, a bottom layer, and a middle layer, the middle layer being placed between and in contact with the top layer and the bottom layer, the three layer semiconductor structure being either a p-n-p structure or an n-p-n structure, and
three electrical contacts, each electrical contact being connected to a different one of the top layer, the bottom layer, and the middle layer,
wherein:
each of the top layer and the middle layer comprises at least one semiconductor having a bandgap higher than the bandgap of a semiconductor of the bottom layer, and
the middle layer has a higher dopant concentration than the top layer.

2. A solar cell according to claim 1, further comprising a passivating layer provided on a surface of the top layer that opposes a surface of the top layer arranged in contact with the middle layer.

3. A solar cell according to claim 1, further comprising a passivating layer provided on a surface of the bottom layer that opposes a surface of the bottom layer in contact with the middle layer.

4. A solar cell according to claim 1, further comprising a contact layer provided between at least one layer of the three layer semiconductor structure and the electrical contact connected to said at least one layer.

5. A solar cell according to claim 1, further comprising an anti-reflecting coating deposited on a top surface of the solar cell.

6. A solar cell according to claim 1, wherein the electrical contact connected to the top layer comprises a grid allowing passage of light through the electrical contact.

7. A solar cell according to claim 1, wherein the electrical contact connected to the top layer comprises a semitransparent conductor.

8. A solar cell according to claim 1, wherein the electrical contact connected to the bottom layer comprises a layer at least partially covering a surface of the bottom layer that opposes a surface of the bottom layer in contact with the middle layer.

9. A solar cell according to claim 1, where the top layer and the middle layer comprise AlₓGa₁₋ₓAs and the bottom layer comprises Al_{y}Ga_{1-y}As where y<x.

10. A solar cell according to claim 1, where the top layer and the middle layer comprise GaAs and the bottom layer comprises Ge.

11. A solar cell according to claim 1, where the top layer and the middle layer comprise AlGaAsP and the bottom layer comprises Ge or GaAs or InP or Si.

12. A method of generating electric power comprising use of at least one solar cell according to claim 1.
